(19) United States
(12) Patent Application Publication
(10) Pub. No.: US 2009/0315965 A1
(43) Pub. Date: Dec. 24, 2009

(54) LED ARRAY MANUFACTURING METHOD, LED ARRAY AND LED PRINTER

(75) Inventors: Kenji Yamagata, Sagamihara-shi (JP); Yoshinobu Sekiguchi, Machida-shi (JP); Takao Yonehara, Kawasaki-shi (JP); Kojiro Nishi, Irvine, CA (US)

Correspondence Address: MORGAN & FINNEGAN Transition Team;C/O Locke Lord Bissell & Liddell, 3 WORLD FINANCIAL CENTER, NEW YORK, NY, 10281-2101, US

(73) Assignee: CANON KABUSHIKI KAISHA, Tokyo (JP)

(21) Appl. No.: 12/373,626

(22) PCT Filed: Oct. 24, 2007
(86) PCT No.: PCT/JP2007/071171

§ 371 Date: Jan. 13, 2009

(30) Foreign Application Priority Data
Oct. 27, 2006 (JP) 2006-293306
Nov. 16, 2006 (JP) 2006-310384
Mar. 9, 2007 (JP) 2007-060362

(51) Int. Cl. B41J 2/385; H01L 21/30; H01L 33/00

(52) U.S. Cl. 347/130; 438/29; 257/88; 257/98; 257/E21.211; 257/E33.069

(57) ABSTRACT

An LED array having no insulating film between the LED structure and the reflector thereof is manufactured by forming a luminescent layer 1102 and a DBR layer 1103 on a first substrate 100 with an insulating layer 1101 interposed between them, patterning the DBR layer and the luminescent layer to make them show an islands-like profile, bonding the DBR layer and a second substrate 110 with an insulating layer 1111 interposed between them, and separating the first substrate and the luminescent layer from each other.

### TECHNICAL FIELD

This invention relates to a light emitting diode (LED) array manufacturing method and an LED printer having an LED array as light source. More particularly, the present invention relates to an LED array manufacturing method having a step of transferring a luminescent layer.

### BACKGROUND ART

A known method of manufacturing an LED array includes forming an LED structure that operates as luminescent region on a GaAs substrate with an AlAs etching sacrifice layer interposed between them and separating the LED structure from the GaAs substrate by selectively removing the sacrifice layer. The LED structure is transferred onto a silicon substrate.

Fujiwara et al., “Imaging Conference Japan 2006, Papers” pp. 11-14 discloses a technique of forming a metal layer on a silicon substrate in advance, arranging an organic insulating film on the metal layer, planarizing the surface and then bonding an LED structure.

While light emitted toward the substrate of an ordinary LED is absorbed by the substrate and not output to the outside, light emitted toward the substrate is reflected by the metal layer to enhance the output of light. In other words, the output of light is enhanced by using a metal layer as reflector.

### DISCLOSURE OF THE INVENTION

However, as a result of research efforts, the inventors of the present invention came to find that, when an organic insulating film is interposed between an LED structure and a metal layer, light emitted toward the substrate is scattered and hence the above-described arrangement requires improvement.

Thus, it is an object of the present invention to provide a novel LED array having no organic insulating film interposed between the LED structure and the reflector, a method of manufacturing such an LED array and an LED printer realized by using such an LED array.

In the first aspect of the present invention, the above object is achieved by providing an LED array manufacturing method including: a step of forming a luminescent layer and a distributed Bragg reflector (DBR) layer on a first substrate with a separating layer interposed between the luminescent or DBR layer and the first substrate; a patterning step of patterning the DBR layer and the luminescent layer to make them show an islands-like profile; a bonding step of bonding the luminescent or DBR layer and a second substrate with an insulating layer interposed between the luminescent or DBR layer and the second substrate; and a separating step of separating the first substrate and the luminescent or DBR layer from each other by etching and removing the separating layer.

In the second aspect of the present invention, there is provided an LED array manufacturing method including: a step of sequentially forming a separating layer, a luminescent layer and a DBR layer on a surface of a first semiconductor substrate and bonding the first semiconductor substrate to a second substrate carrying a semiconductor circuit formed thereon by way of an insulating layer; a step of transferring the luminescent layer and the DBR layer on the second substrate by etching off the separating layer; a step of turning the transferred luminescent layer into an array of a plurality of luminescent sections; and a step of electrically connecting the plurality of luminescent sections and electrode parts of the semiconductor circuit for controlling on/off of the luminescent sections.

In the third aspect of the present invention, there is provided an LED printer including: an LED array prepared by an LED array manufacturing method in the first or second aspect of the present invention; a photosensitive drum for writing an electrostatic latent image, using the LED array as light source; and a charger; no rod lens array being arranged between the photosensitive drum and the LED array.

In the fourth aspect of the present invention, there is provided an LED printer including: an LED array having a luminescent layer of a compound semiconductor formed on a silicon substrate and a DBR layer arranged between the silicon substrate and the luminescent layer; a photosensitive drum for writing an electrostatic latent image, using the LED array as light source; and a charger; no rod lens array being arranged between the photosensitive drum and the LED array.

In the fifth aspect of the present invention, there is provided an LED array including a DBR layer and a luminescent layer formed in the mentioned order on a silicon substrate having a drive circuit with an insulating layer interposed between the DBR layer and the silicon substrate; no organic insulating film being interposed between the luminescent layer and the DBR layer operating as reflector; the drive circuit and the luminescent layer being electrically connected to each other directly or indirectly by way of the DBR layer.

In the sixth aspect of the present invention, there is provided an LED printer including: an LED array in the fifth aspect of the present invention; a photosensitive drum for writing an electrostatic latent image, using the LED array as light source; and a charger; no rod lens array being arranged between the photosensitive drum and the LED array.

In the seventh aspect of the present invention, there is provided a luminescent device including: a DBR layer having a semiconductor film and a luminescent layer formed in the mentioned order on a substrate; a first electrode for flowing a drive current to the luminescent layer being electrically connected to the luminescent layer at the side opposite to the DBR layer; a second electrode for flowing a drive current to the luminescent layer being electrically connected to the semiconductor film of the DBR layer at the side of the luminescent layer.

Thus, according to the present invention, there is provided a novel LED array having no organic insulating film between a DBR layer operating as reflector and a luminescent layer as well as a method of manufacturing such an LED array and an LED printer using such an LED array.

Further features of the present invention will become apparent from the following description of exemplary embodiments with reference to the attached drawings.

### BRIEF DESCRIPTION OF THE DRAWINGS

FIGS. 1A and 1B are schematic cross sectional views of the first substrate and the second substrate of an LED array.

FIG. 2 is a schematic cross sectional view of the luminescent layer of an LED array according to the present invention.

FIG. 3 is a schematic cross sectional view of an LED array, illustrating a step in the process of a first embodiment of the present invention.

FIG. 4 is a schematic cross sectional view of the LED array, illustrating another step in the process of the first embodiment of the present invention.

FIG. 5 is a schematic cross sectional view of the LED array, illustrating still another step in the process of the first embodiment of the present invention.

FIG. 6 is a schematic cross sectional view of an LED array, illustrating a step in the process of another embodiment of the present invention.

FIG. 7 is a schematic cross sectional view of the LED array, illustrating another step in the process of the another embodiment of the present invention.

FIG. 8 is a schematic cross sectional view of an LED array, illustrating a step in the process of still another embodiment of the present invention.

FIG. 9 is a schematic cross sectional view of the LED array, illustrating another step in the process of the still another embodiment of the present invention.

FIG. 10 is a schematic cross sectional view of the LED array, illustrating still another step in the process of the still another embodiment of the present invention.

FIG. 11 is a schematic cross sectional view of the LED array, illustrating still another step in the process of the still another embodiment of the present invention.

FIG. 12 is a schematic cross sectional view of the LED array, illustrating still another step in the process of the still another embodiment of the present invention.

FIG. 13 is a schematic illustration of an LED array according to the present invention.

FIG. 14 is a schematic illustration of an LED array according to the present invention.

FIG. 15 is a schematic illustration of an LED printer according to the present invention.

FIG. 16 is a schematic cross-sectional view, illustrating a layer configuration on a first substrate according to the present invention.

FIG. 17 is a schematic illustration of an LED printer according to the present invention.

FIG. 18 is a schematic cross sectional view of the fifth embodiment of the present invention.

### BEST MODE FOR CARRYING OUT THE INVENTION

### First Embodiment: LED Array Manufacturing Method

Now, this embodiment of the present invention will be described by referring to the related drawings.

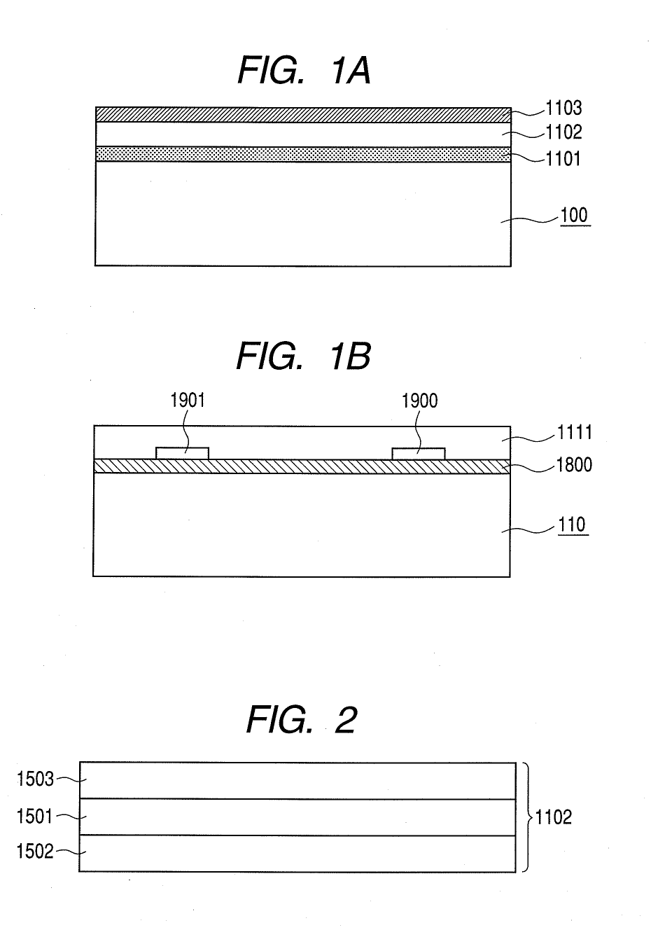

Firstly, a first substrate for forming an LED thereon and a second substrate where a luminescent layer is transferred will be described by referring to FIGS. 1A and 1B.

As illustrated in FIG. 1A, firstly a luminescent layer 1102 including an active layer and a DBR layer 1103 are formed on the first substrate 100 with a separating layer 1101 interposed between them.

The first substrate 100 is a substrate for forming an LED (light emitting diode) thereon. The first substrate 100 can grow a compound semiconductor film for the LED. When the group III-V compound type that is based on GaAs is made to grow on the first substrate, the first substrate may typically be a GaAs substrate or a Ge substrate showing a lattice constant close to that of GaAs. When a GaAs substrate is employed, the substrate may contain one or more than one elements of the same groups such as Al and/or P. Additionally, the first substrate may contain one or more than one impurities for producing the p-type or n-type depending on the device.

A separating layer 1101, a luminescent layer 1102 and a DBR layer 1103 are sequentially formed by epitaxial growth on the first substrate 100 typically by MOCVD or MBE. The separating layer 1101 is a layer made of a material that can be selectively etched relative to the luminescent layer 1102. The material may typically be AlAs or AlxGa1-xAs (1·x·0.7). The separating layer having such a composition is selectively etched by means of a hydrofluoric acid solution.

The luminescent layer 1102 is a compound semiconductor layer that operates as luminescent device. Materials that can be used for the luminescent layer include GaAs, AlGaAs, InGaAs, GaP, InGaP and AlInGaP having a pn junction. FIG. 2 illustrates a specific structure of the luminescent layer 1102 that includes an active layer 1501 sandwiched between clad layers 1502, 1053.

The DBR layer 1103 can epitaxially grow relative to the first substrate 100 and has a structure of laying a plurality of pairs of layers, the layers of each pair having different refractive indexes relative to the wavelength of the LED to be formed.

Thus, each pair has a high refractive index layer and a low refractive index layer. A layer formed by laying a plurality of such pairs is referred to as a Bragg reflection film or a DBR mirror (DBR layer).

For the Bragg reflection film, the film thicknesses d1, d2 of the two films of different types having different refractive indexes of each pair are so selected as to make the optical film thickness n×d equal to ¼ wavelengths and m pairs (m=natural number not less than 2) of films of the two types are used to achieve a reflectance that corresponds to the m pairs. A high reflectance can be achieved by using a small number of pairs when the difference of the refractive indexes of the layers of the Bragg reflection film is large. For the purpose of the present invention, it is desirable to optimize the conditions under which the DBR is formed in the design phase so that it can reflect light of a specific wavelength by not less than 70%, preferably not less than 80%, most preferably not less than 90%.

For instance, layers of two different types that are different in terms of Al content ratio in AlGaAs are laid alternately to obtain a DBR layer. It is desirable from the viewpoint of selectively removing the above-described separating layer that the Al content ratio, or x in the composition expressed by AlxGa1-xAs, is not more than 0.8, preferably not more than 0.7, more preferably not more than 0.6, most preferably not more than 0.4. The lower limit value of x is typically nil

In any case, the low refractive index layers of the DBR layer whose refractive index is lower than the remaining layers is made of a material selected from AlxGa1-xAs (0·x·0.8), AlInGaP type materials and AlGaP type materials. When the material of the separating layer is selected from AlAs or AlxGa1-xAs (0.7·x·1.0) and the separating layer is selectively etched off, it is important that the combination of the related materials can make the low refractive index layer hardly damageable. Note that it is possible to selectively remove the separating layer without significantly depending on the Al content ratio when an AlAs layer is selected for the separating layer and an AlInGaP type material or an AlGaP type material is used for the low refractive index layers.

The DBR layer may be configured particularly to show a high resistance against hydrofluoric acid by a combination of high refractive index layers and low refractive index layers selected from the three examples listed below.
1) Al0.6Ga0.4As/Al0.2Ga0.8As
2) AlInGaP/Al0.2Ga0.8As
3) AlGaP/Al0.2Ga0.8As

When preparing a laser, 30, 40 or more pairs of layers may be required to achieve a reflectance of not less than 99.9%, several to 10 pairs of layers may be sufficient for an LED that is typically required to show a reflectance of not less than 90%.

The second substrate 110 to which a luminescent layer 1102 is transferred may or may not carry a semiconductor drive circuit 1800 formed thereon to drive an LED. FIG. 1B illustrates a second substrate that is a silicon substrate where a drive circuit 1800 is formed for a basic configuration.

Electrode pads 1900, 1901 are formed on the surface of the substrate 110 so as to be electrically connected to an LED. An organic insulating film 1111 is formed thereon in order to electrically separate the LED section to be moved thereto and the drive circuit.

When a simple silicon substrate having no drive circuit is employed as the second substrate 110, it is only necessary to omit the drive circuit 1800 and the electrode pads 1900, 1901 in FIG. 1B.

It is preferable that the organic insulating film 1111 also operates as adhesive for bonding the first substrate 100 and the second substrate 110 together and hence is sticky and flat.

For example, a film formed by spin coating an organic compound such as polyimide may typically be used for the organic insulating film. It may be needless to say that a material other than polyimide may also be used for the organic insulating film 111 when the material satisfies the requirements including an insulating property, adhesiveness and thermal plasticity. While an organic insulating film is described above as an example, an inorganic (e.g., SOG) insulating film can also be applied to the present invention.

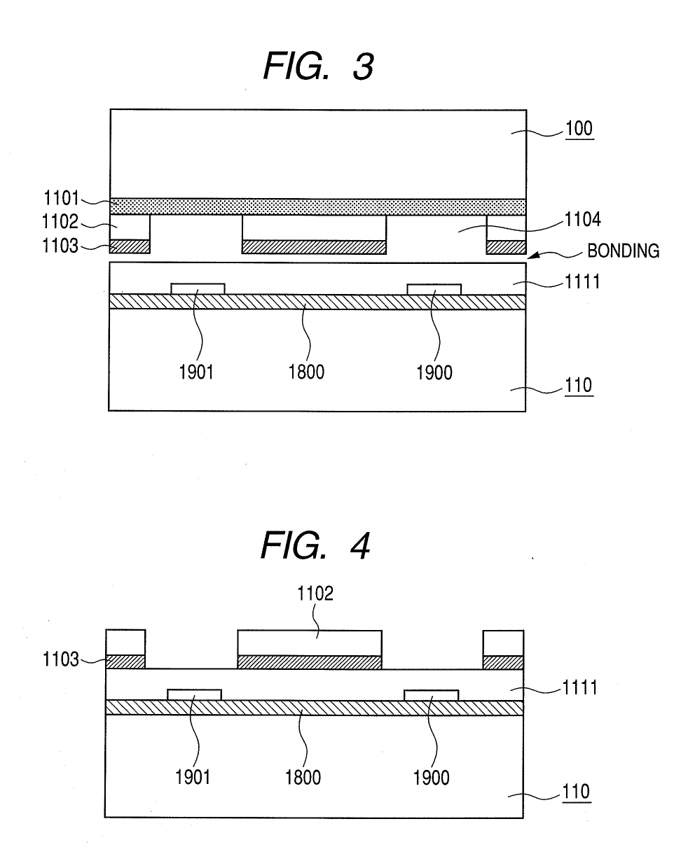

Now, the bonding step of bonding the first substrate 100 and the second substrate 110 will be described below by referring to FIG. 3.

The DBR layer 103 and the luminescent layer 1102 formed on the surface of the first substrate 100 are subjected to a patterning process of forming grooves to divide them into islands-like regions in during the patterning process. More specifically, the DBR layer and the luminescent layer are subjected to an etching process to expose the separating layer 1101. While it is desirable that the etching process is terminated when the separating layer comes out to become exposed, the subsequent processes are not adversely affected if the etching process goes through the separating layer and gets to the substrate. The separated (first) substrate can be reused when the etching process can be stopped in the separating layer. A layer that operates as an etching stop layer may be arranged between the first substrate 100 and the separating layer 1101.

Then, the surface where the DBR layer 1103 and the luminescent layer 1102 are patterned to illustrate an islands-like profile is bonded to the organic insulating film 1111 of the second substrate as illustrated in FIG. 3. At this time, the two substrates are preferably aligned with each other before they are bonded to each other for the purpose of electrically connecting the LED and the drive circuit. In the bonding step, preferably the two surfaces to be bonded are brought into contact with each other and heated to raise the bonding strength. While the heating temperature varies depending on the material of the insulating film, the heating temperature is about tens of several ° C. to 300° C. in the case of an organic insulating film. As a result of the bonding operation, spaces are formed in the grooves separating the surface layer into islands-like regions along the interface of the bonding.

FIG. 4 schematically illustrates the transferring step of etching the separating layer 1101.

The spaces (grooves) produced as a result of the above-described bonding step operate as flow paths when etching solution is introduced. Etching solution that is a hydrofluoric acid solution is injected into the flow paths. While the entire substrate may simply be immersed into the solution for the purpose of injecting the solution, the interface of the bonding preferably is exposed to a jet flow of the solution and/or ultrasonic waves in order to accelerate penetration of the solution.

The separating layer exposed to the inside of the flow paths is selectively etched by the hydrofluoric acid solution that penetrates the flow paths so that consequently the DBR layer 1103 and the luminescent layer 1102 are transferred (moved) onto the second substrate 110 as illustrated in FIG. 4.

In this way, an LED array of this embodiment is manufactured.

Now, an exemplary technique of electrically connecting the luminescent layer and the drive circuit 1800 when the drive circuit is arranged on the second substrate 110 will be described below.

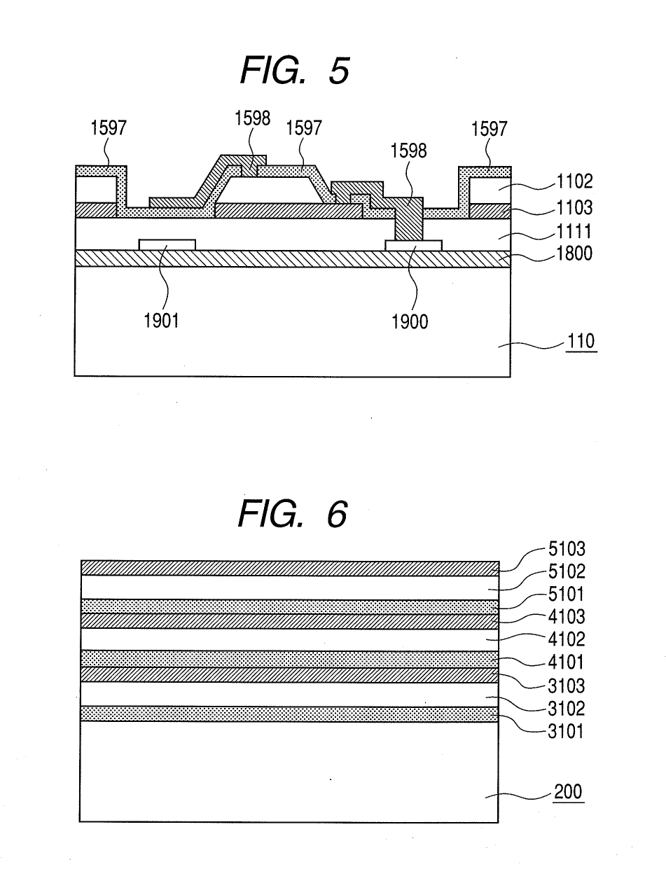

FIG. 5 schematically illustrates the step of electrically connecting the LED and the drive circuit 1800.

The transferred luminescent layer 1102 includes a P layer and an N layer (P and N indicates the respective conduction types). The luminescent layer is partly etched until the surface conduction type layer and the layer of the opposite conduction type are exposed and then the luminescent is entirely covered by an insulating film. Then, contact holes are formed in areas where electric contact is to be established with the electrodes. At this time, via holes are formed to allow them to run through the organic insulating layer in order to connect the electrode pads of the drive circuit and the LED. Then, the electrode material is deposited and patterned to connect the LED and the drive circuit.

As a matter of fact, a plurality of LEDs is produced by patterning to form an LED array that is controlled by the drive circuit.

While the luminescent layer is electrically connected to the drive circuit by way of the DBR layer 1103 in FIG. 5, it is also possible to expose the surface conduction type layer and the layer of the opposite conduction type and directly electrically connect the exposed part and the drive circuit.

### (Layer Arrangement on the First Substrate)

While the luminescent layer and the DBR layer are formed on the first substrate 100 with a separating layer interposed between them in the mentioned order as viewed from the separating layer in FIGS. 1A and 1B, it is also possible to form the DBR layer and the luminescent layer in the mentioned order as viewed from the separating layer. With such an arrangement, it is necessary to provide a step of bonding them to a temporary substrate and subsequently bonding them to the second substrate as will be described hereinafter. When no such a temporary substrate is used, the separating step is conducted after the above-described bonding step (of bonding the DBR layer and the second substrate). When, on the other hand, a temporary substrate is used, the separating step is conducted after bonding the luminescent layer and the temporary bonding substrate and subsequently the bonding step of bonding the DBR layer and the second substrate is conducted.

The present invention also covers arrangement where another layer is interposed between the first substrate 100 and the separating layer 1101 or between the separating layer and the luminescent layer 1102.

### (Islands-Like Patterning)

The above-described patterning step is a step of patterning the luminescent layer to make the luminescent layer show an islands-like profile by device isolation and include a plurality of luminescent sections. The plurality of luminescent sections may be formed so as to make them correspond to individual luminescent spots by device isolation after the separating step.

It is also possible that each of the luminescent sections of the luminescent layer that are made to show an islands-like profile by device isolation is made to correspond to each luminescent spot in the patterning step.

The patterning step of patterning the DBR layer and the luminescent layer to make them show an islands-like profile is also a step of forming regions where a plurality of luminescent devices are arranged in array. Preferably, the size of the regions is made to agree with the chip size that is used when dicing the second substrate.

As pointed out above, the patterning step of patterning the DBR layer and the luminescent layer to make them show an islands-like profile is also a step of forming regions where a plurality of luminescent devices are arranged in array. Alternatively, the size of the regions may be made smaller than the chip size that is used when dicing the second substrate and the gaps separating the regions may be made equal to the gaps separating chips.

### (DBR/Luminescent Layer/DBR)

It is also possible to sandwich the luminescent layer on the first substrate 100 between the DBR layer 1103 and another DBR layer that is different from the above DBR layer.

Thus, with the above-described first embodiment, an LED thin film having a DBR reflection layer is transferred onto a substrate (having a drive circuit if necessary) so that the LED shows a luminance that is enhanced if compared with an ordinary LED.

As described above, a DBR layer is arranged immediately below the luminescent layer to minimize the reflection loss and raise the luminance unlike an LED provided with a metal reflector layer with an organic insulating layer interposed between them described earlier under related background art.

Additionally, voids attributable to bonding can hardly exist along the reflection interface to improve the reliability of the manufacturing process. Still additionally, the luminescent layer is transferred onto a silicon substrate to improve the effect of diffusing heat if compared with the LED formed on a GaAs substrate. Then, as a result, it is possible to avoid the substrate from being distorted and the luminance from being reduced by heat.

As described above, with this embodiment of the invention, a compound semiconductor substrate (or a Ge substrate) is used as luminescent device substrate and a separating layer, a luminescent layer and a DBR layer are sequentially formed on the compound semiconductor substrate.

Then, the surface DBR layer is bonded to a silicon substrate carrying or not carrying a drive circuit formed thereon by way of an insulating layer and the separating layer is removed by etching to transfer the luminescent layer and the DBR layer onto the silicon substrate carrying or not carrying a drive circuit formed thereon.

With this arrangement, it is possible to improve the heat diffusing characteristic if compared with the conventional DBR method of directly using a compound semiconductor substrate. Additionally, when the luminescent layer and the DBR layer are transferred onto a silicon substrate carrying a drive circuit formed thereon, it is possible to remarkably reduce the installation of wire bonding between the compound semiconductor substrate and the drive circuit when mounting the LED array.

Additionally, it is possible to reduce the radiation angle of the LED by sandwiching the luminescent layer between reflection layers to realize a layer arrangement of a DBR layer, a luminescent layer and a DBR layer for the compound semiconductor film to be transferred. Thus, in the case of an electronic photography apparatus (printer) using an LED array as light source, it is possible to omit the use of a rod lens array for converging light irradiated from the LED onto the surface of a photosensitive drum.

When the above-described embodiment is compared with the known method of transferring a luminescent device layer, utilizing a metal reflection layer, after bonding it by way of the metal reflection layer and the adhesive layer arranged thereon as described in Fujiwara et al., “Imaging Conference Japan 2006, Papers” pp. 11-14, the reflection effect of the embodiment is high because of the DBR reflection layer arranged immediately below the luminescent layer. Additionally, the embodiment provides a high reliability because emitted light is hardly affected by void attributable to bonding. Still additionally, absence of a step of forming a metal reflection film means absence of a step of eliminating the level differences of the metal reflection film, using an insulating film, for the purpose of planarization. Therefore, it is possible to reduce the total thickness of the adhesive layer to improve the heat diffusing effect. Furthermore, the overall cost can be reduced as described below.

It is possible to repeat a step of continuously epitaxially growing a plurality of sets of layers, each set including a separating layer, a luminescent layer and a DBR layer, on a compound semiconductor substrate and transferring the uppermost set onto a drive circuit. Then, it is possible to obtain a plurality of substrates onto which a luminescent layer is transferred in a single epitaxial growth process. Thus, it is possible to reduce the overall cost.

When a separating layer, a luminescent layer and a DBR layer are made to grow on a compound semiconductor substrate in the mentioned order, it is only necessary to bond the uppermost DBR layer onto the insulating film on a drive circuit substrate. However, when a separating layer, a DBR layer and a luminescent layer are made to grow in the mentioned order, it is also possible to transfer the layers with the following arrangement. The uppermost luminescent layer is once bonded to a temporary substrate and transferred onto the temporary substrate by separating it from the compound semiconductor substrate by separating them along the separating layer and then the luminescent layer and the DBR layer are transferred from the temporary substrate to the drive circuit substrate. Thus, it is possible to prepare a luminescent device by way of a double transfer.

When forming luminescent spots of a small size on the surface of a photosensitive member without using a rod lens, it is sometimes unsatisfactory for realizing a spot size of a high resolution printer (20·mø@1,200 DPI) simply by arranging a DBR on the substrate side interface and/or the substrate surface to improve the directivity. However, this problem can be avoided by reducing the luminescent area of the device and hence the dimensions of the LED device itself. For example, it is desirable to design an LED device whose luminescent area is less than a half of the size of a spot on the surface of a photosensitive member for forming a desired latent image.

### Second Embodiment: Multi-Epitaxial Growth

Now, the second embodiment will be described below by referring to FIG. 6. This embodiment is designed for cost reduction by extending the process illustrated in FIGS. 1A through 5.

FIG. 6 is a schematic illustration of the layers on a first substrate of the second embodiment.

While a separating layer, a luminescent layer and a DBR layer are sequentially arranged on a first substrate in the first embodiment, a plurality of sets of layers, each set including three layers of a separating layer, a luminescent layer and a DBR layer, are formed on a first substrate by epitaxial growth. Thus, a plurality of members, or sets of layers, each set including three layers of a separating layer, a luminescent layer and a DBR layer, is formed as multilayer structure.

FIG. 6 illustrates three sets of layers, each set including a separating layer, a luminescent layer and a DBR layer, formed by epitaxial growth. In FIG. 6, 3101, 4101 and 5101 denote respective separating layers and 3102, 4102 and 5102 denote respective luminescent layers, while 3103, 4103 and 5103 denote respective DBR layers.

The objective of this embodiment is to form a plurality of sets of layers to be transferred at a time and prepare a plurality of film-transferred substrates by transferring each set onto a second substrate in order to reduce the manufacturing cost.

Now, the steps of the transfer process of this embodiment will be described below.

The DBR layer 5103 and the luminescent layer 5102 of the uppermost set are subjected to patterning and etching to expose the separating layer 5101 out of a plurality of sets of separating layers, luminescent layers and DBR layers formed on a first substrate 200 by epitaxial growth as in the case of the first embodiment. The subsequent steps including a bonding step, a separating step and a device preparing step that comes after the film transfer are same as those of the first embodiment.

Note, however, that the separating layer 4101, the luminescent layer 4102 and the DBR layer 4103 are left on the surface of the first substrate 200 separated after the film transfer so that the substrate can be used again for the first step of the next transfer process.

In this way, it is possible to produce a plurality of film-transferred second substrates by using a single first substrate.

### Third Embodiment: Use of a Temporary Substrate

Now, the third embodiment of the present invention, which is a variation of the film transfer method according to the present invention will be described below by referring to FIG. 8.

FIG. 8 schematically illustrates a first substrate 300.

Unlike the first embodiment, a separating layer 8301, a DBR layer 8303 and a luminescent layer 8302 are sequentially formed on the surface of the substrate by epitaxial growth.

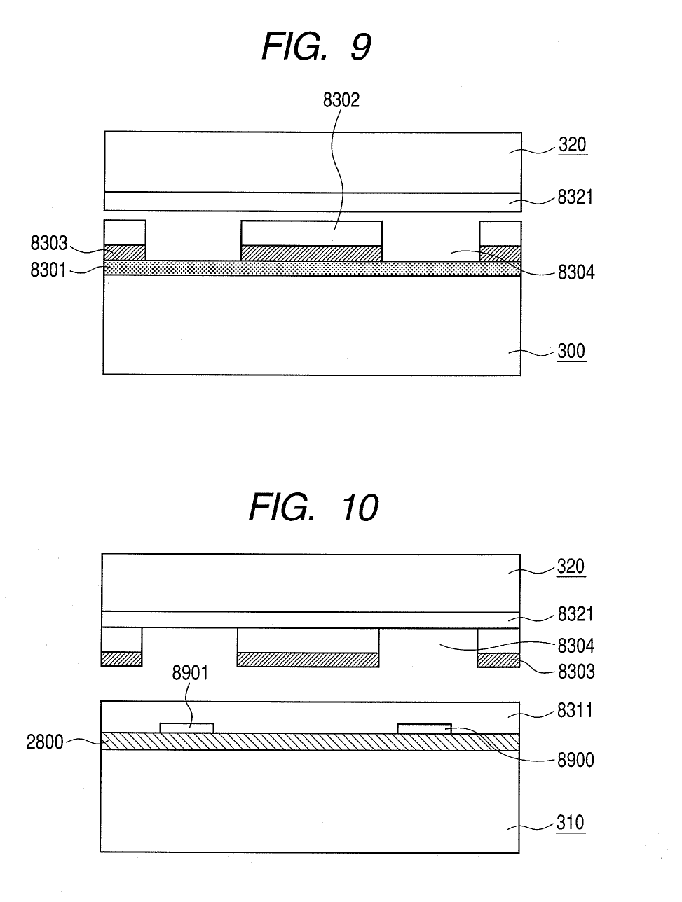

FIG. 9 is a schematic illustration of the bonding step on a temporary substrate 320.

Like the first and second embodiments, after patterning the layers to make them show an islands-like profile, the luminescent layer 8302 and the DBR layer 8303 are etched to expose the separating layer 8301.

Thereafter, the surface of the layers is bonded to the temporary substrate 320 having a temporary bonding function. Then, the separating layer is etched off as in the preceding embodiments to temporarily transfer the luminescent layer and the DBR layer onto the temporary substrate.

FIG. 10 is a schematic illustration of the retransfer step from the temporary substrate 320 to a proper substrate.

As in the case of the first and second embodiments, a second substrate 310 where a drive circuit is formed and an organic insulating film 8311 is applied to the surface is prepared. Then, the separating surface of the film transferred onto the temporary substrate 320 is bonded to the second substrate 310 and, after securing the required bonding strength relative to the second substrate typically by heating, the temporary substrate is separated. Techniques that can be used for separating the temporary substrate include a technique of selectively dissolving the adhesive of the temporary substrate for the separation and a technique of using an adhesive agent whose adhesiveness is deactivated when irradiated with ultraviolet rays.

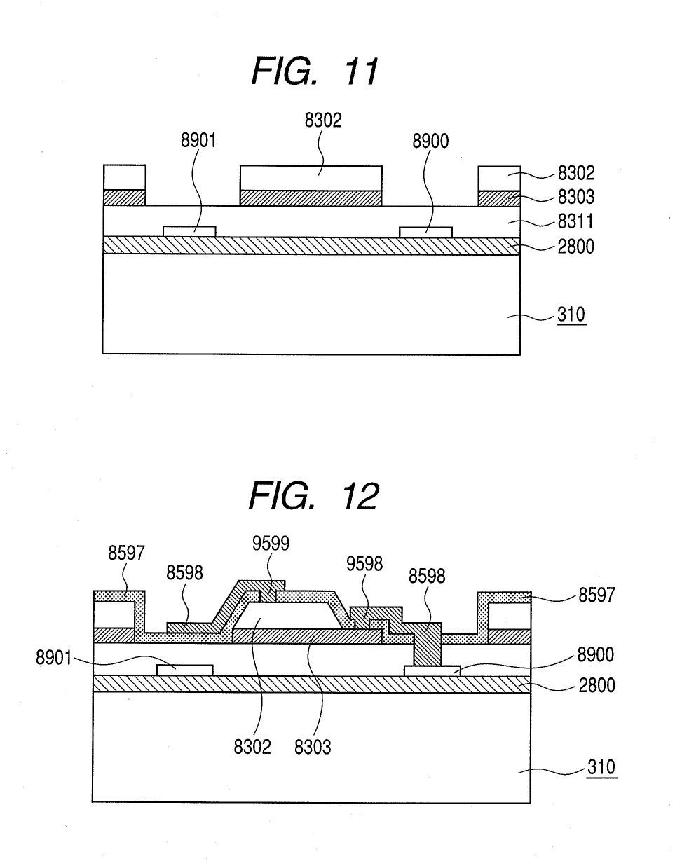

Since the steps illustrated in FIGS. 11 and 12 are same as those of the first and second embodiments, they will not be described here any further. This embodiment can be applied to a plurality of sets of layers formed by epitaxial growth as in the case of the second embodiment. In FIG. 11, 310 denotes a second substrate and 2800 denotes a drive circuit whereas 8900 and 8901 denote electrode pads and 8311, 8303 and 8302 respectively denote an organic insulating film, a DBR layer and a luminescent layer. In FIG. 12, 8597 denotes an insulating film (of SiO2 or SiN) and 8598 denotes a metal wire. In FIG. 12, 9599 indicates the connection with a p-contact layer and 9598 denotes the connection with an n-contact layer.

### Fourth Embodiment: the Second Aspect of the Invention

In the second aspect of the present invention, there is provided a luminescent device arranged on a silicon substrate with a DBR mirror interposed between them.

It is possible to obtain a contact type printer head that does not require a rod lens by forming a so-called micro-cavity LED equipped with a DBR and transferring the micro-cavity LED onto a silicon substrate, thereby realizing a highly directive spot. A method of manufacturing such a LED array includes the following steps.
(Step 1) Firstly, a separating layer, a luminescent layer and a DBR layer are formed on the surface of a first semiconductor substrate in the mentioned order and the layers are bonded to the insulating film of a second substrate where a semiconductor circuit is formed.
(Step 2) The luminescent layer and the DBR layer of the first substrate are transferred onto the second substrate by etching off the separating layer.
(Step 3) The transferred luminescent layer is turned into an array of a plurality of luminescent sections and then the plurality of luminescent sections and the electrode parts of the semiconductor circuit for controlling turning on/off of the luminescent sections are electrically connected.

Preferably, in step 1, the luminescent layer and the DBR layer are subjected to a patterning process in advance to make them show an islands-like profile. Grooves are formed in the luminescent layer and the DBR layer in the patterning process. Preferably, the grooves have a depth of getting to the separating layer. The step 3 of turning the luminescent layer into an array of a plurality of luminescent sections is a step of forming an array of a plurality of luminescent sections from the luminescent layer that is patterned to show an islands-like profile by way of an ordinary process. For example, grooves are formed to surround areas that correspond to luminescent spots (e.g., squares of 20·m×20·m in plan view). It is sufficient for the grooves to have a depth that substantially isolate the regions of the conduction type found on the surface in an intra-planar direction. Of course, the grooves may have a depth getting to the active layer.

### Fifth Embodiment: Electric Connection Utilizing DBR Layer

A luminescent device of this embodiment will be described below by referring to FIG. 18.

Referring to FIG. 18, 2810 denotes a substrate (which may typically be a silicon substrate, a transparent substrate or an SOI substrate) and 2811, 2812 and 2813 respectively denote an insulating layer, a luminescent layer and a DBR layer. The DBR layer is formed by a plurality of semiconductor films (a plurality of pairs of layers, each pair having layers showing different refractive indexes).

In FIG. 18, 2877, 2897, 2887 denote insulating layers and 2898 and 2888 respectively denote a first electrode and a second electrode.

The first electrode 2898 is arranged at the side of the luminescent layer opposite to the DBR layer in order to flow a drive current to the luminescent layer.

The second electrode 2888 for flowing a drive current to the luminescent layer 2812 is electrically connected to the semiconductor films of the DBR layer arranged at the side of the luminescent layer.

When the DBR layer is formed by laying n pairs (e.g. 10 pairs) of semiconductor films, each pair having a first semiconductor film and a second semiconductor film, the expression of the semiconductor films arranged at the side of the luminescent layer refers to the n/2 pairs of semiconductor films located at the side of the luminescent layer in terms of the film thickness of the DBR layer. In other words, the second electrode is electrically held in contact with the semiconductor films (of the DBR layer) showing a thickness of ½ of the film thickness of the DBR layer as viewed from the interface with the luminescent layer. Of course, it is possible to bring all the semiconductor films of the DBR layer or the semiconductor films in the inside of the DBR layer into direct contact with the second electrode.

In FIG. 18, the DBR layer 2813 formed by a semiconductor multilayer film and the luminescent layer 2812 are arranged on the substrate 2810 in the mentioned order and there is a region 3800 on the DBR layer where the luminescent layer is not found. A metal layer may be interposed between the DBR layer 2813 and the insulating film 2811.

Then, the first electrode 2898 for flowing a drive current to the luminescent layer 2812 is electrically connected to the luminescent layer 2812 at the side of the latter opposite to the DBR layer 2813. Additionally, the second electrode 2888 for flowing a drive current to the luminescent layer 2812 is electrically connected to the semiconductor multilayer film 2813 at the side of the luminescent layer 2812 in the region 3800.

With the above-described arrangement, it is possible to reduce the influence of a high resistance in the multilayer direction of the DBR layer if compared with an arrangement where the electrode is placed at the side of the DBR layer 2813 opposite to the luminescent layer 2812 for flowing a drive current.

The DBR layer may be of the n-type or the p-type depending on the film arrangement and the transfer process of the luminescent layer.

Note that, since the DBR layer is normally a multilayer member of semiconductor films, a high resistance arises when carriers are made to flow in the multilayer direction.

However, according to the present invention (FIG. 18), it is possible to avoid a high resistance when carriers are made to flow in a direction perpendicular to the multilayer direction of the DBR and the DBR is of the n-type.

In other words, the influence of a high resistance can be reduced when the DBR layer is an n-type DBR layer.

It is also possible to physically bring the semiconductor film (part of the semiconductor multilayer film) defining the interface of the luminescent layer 2812 and the DBR layer into contact with the second electrode 2888. If the influence of the interface is strong when interface and the second electrode is brought into direct contact, it is also possible to bring the semiconductor film located in the inside from the interface by several semiconductor film layers with the second electrode. Preferably, the DBR layer 2813 is functionally divided for use as illustrated in FIG. 18. More specifically, it is highly preferable that the DBR layer is used and held in contact with the electrode in the part of the region 3800 and the part other than the region 3800 (which is the part immediately below the luminescent layer) is used to raise the rate of taking out light from the luminescent layer.

When the DBR layer that operates as optical reflection layer is arranged directly on the luminescent active layer or the clad layer, it is possible to avoid absorption of light by the contact layer (that can be arranged on the top of the DBR layer in order to reduce the connection resistance) that absorbs the emission wavelength of itself. Of course, the present invention does not exclude arranging a contact layer between the luminescent layer 2812 and the DBR layer.

When an insulator is interposed between the device region that includes the luminescent layer and the reflector metal layer, the influence of light absorption by the insulator is significant but can be suppressed by arranging the DBR layer that operates as optical reflection layer directly on the luminescent active layer or the clad layer.

This embodiment can suitably be applied when the first electrode and the second electrode need to be drawn out independently from each device as in the case of matrix drive operation because the DBR layer arranged immediately below the luminescent active layer is used as electrode and the electrode and the substrate are electrically isolated from each other by means of a insulating layer so as to operate independently.

More specifically, it is possible to provide two advantages of the DBR layer at the same time including the advantage of a mirror reflection effect of multiplying the intensity of luminescence and that of taking the role of operating as an independent lower electrode of the LED device by adding an impurity to raise the carrier density and lower the resistance.

Additionally, if compared with a conventional device that employs a compound semiconductor substrate for mounting a luminescent device such as an LED, it is possible to improve the thermal conductivity to a level higher by a number of times by using a silicon substrate.

Substrates that can be used for “the substrate 2810” include a glass substrate, a quartz substrate, a metal substrate, a ceramic substrate and a substrate coated with an insulating film in addition to a silicon substrate. The thickness of the substrate is typically within a range between 300·m and 1,000·m, preferably within a range between 400·m and 800·m from the viewpoint of securing the necessary strength and the process. It is also possible to arrange a drive circuit (1800 in FIG. 5) on or inside the silicon substrate that is the substrate 2810. If such is the case, the second electrode 2888 and the electrode 1900 (FIG. 5) at the side of the drive circuit are electrically connected as illustrated in FIG. 5.

“The insulating layer 2811” is a film made of an organic material. A film made of an organic material typically refers to an organic insulating film made of a polyimide type material or some organic insulating film. In other words, a film made of an organic material may typically be a polyimide film. More specifically, a positive type photosensitive polyimide may be used for the insulating film. Of course, the part of the photosensitive insulating layer that is exposed to light no longer remains substantially photosensitive after the exposure. Not a positive type but a negative type photosensitive polyimide or a non-photosensitive polyimide may also be employed when a mask is additionally used. Polyimide is commercially available from HD MycroSystems, Ltd. to name only a few.

Photosensitive polyimide is described in detail in Japanese Patent Application Laid-Open No. 2005-012034. More specifically, alcohol having a double bond (e.g., hydroxyethyl methacrylate) is made to react with an aromatic anhydride to produce a dicarboxylic acid and then a diamine is made to react with the above reaction product to produce a polyamide, which corresponds to a structure obtained by substituting a polymerizing structure having a double bond for the carboxylic group of a polyamic acid. A photosensitive polyimide is obtained by dissolving the polymer into a polar solvent such as NMP (n-methylpyrrolidone) with a photoinitiator, an intensifier and a bonding promoter. Some other organic material film may be used for bonding the compound semiconductor substrate and the silicon substrate. An epoxy type adhesive layer may be employed for the purpose of the present invention instead of polyimide.

An inorganic type insulating oxide film such as silicon oxide film may be used for the insulating layer 2811 instead of an organic material film. A siloxane type resin may also be used for the purpose of the present invention.

When the substrate 2810 has a circuit region produced by utilizing on and/or the inside of the silicon substrate, a silicon oxide insulating film may be formed by utilizing spin-on-glass (SOG) in order to improve the planarity of the circuit region. Of course, insulating films of a plurality of different types may be laid one on the other to form a multilayer insulating film. Further, an insulating film may be formed by utilizing an organic material such as polyimide. It is effective from the productivity point of view to apply an organic material by spin coating, bonding the substrate 2810 to the first substrate, using a pre-baking step for volatilizing the solvent to improve the adhesiveness, and subsequently improving the tight contact.

For the purpose of the present invention, it is possible to utilize a photosensitive polymer sheet for the insulating film. Such a polymer sheet preferably shows adhesiveness by itself. When an insulating film is formed on the second substrate or an insulating film is formed on the first substrate, the insulating film may be formed by way of a heating and pressure bonding step. The insulating film may be formed by spin-coating a solution of an organic material (e.g., a photosensitive polyimide). Alternatively, a photosensitive polyimide sheet that is a filmy sheet of a photosensitive polyimide may be utilized.

It is also possible to omit the insulating layer when the substrate 2810 is an insulating substrate such as a glass substrate. It is also possible to interpose a region of a metal or an alloy between the insulating layer 2811 and the substrate 2810. Such a metal may be used to raise the effect of diffusing heat. When the effect of diffusing heat is degraded as a result of using a DBR layer 2813, a metal layer showing a good thermal conductivity may be arranged between the DBR layer 2813 and the insulating layer 2811. When such a metal layer is used, the interface of bonding may be between the DBR layer 2813 and the metal layer or the metal layer may be formed on the DBR layer 2813 and then bonded to the insulating layer 2811. It is possible to suppress the change of the refractive index in the DBR layer by arranging a metal layer between the DBR layer 2813 and the insulating layer as the metal diffuses in the DBR layer. “The luminescent layer 2812” is not subjected to any particular limitations. In other words, any material selected from the materials described above and hereinafter may be used for the luminescent layer 2812. For example, a double-heterojunction type material using AlGaAs or a homo junction type material using GaAsP may be used. When the luminescent layer is made to show a double hetero type structure, a contact layer may be arranged between the clad layer and the DBR layer.

Any material selected from the materials described above and hereinafter may be used for “the DBR layer 2813”. The material of the low refractive index layer of the DBR layer that shows a refractive index lower than the remaining layers may be selected from AlxGa1-xAs (0·x·0.8), AlInGaP type materials and AlGaP type materials. The material of the etching sacrifice layer that contributes to the separation from the growing substrate is selected from AlAs and AlxGa1-xAs (0.7·x·1.0). When the separating layer is selectively etched off, it is preferable to combine it with a material that can make the low refractive index layer hardly damageable. It is possible to selectively remove the separating layer without significantly depending on the Al content ratio when an AlAs layer is selected for the sacrifice layer and an AlInGaP type material or an AlGaP type material is used for the low refractive index layer. Three examples are shown below for the combination of (high refractive index layers/low refractive index layers) for the DBR layer showing a high resistance against hydrofluoric acid, although the present invention is by no means limited thereto.
1) Al0.6Ga0.4As/Al0.2Ga0.8As
2) AlInGaP/Al0.2Ga0.8As
3) AlGaP/Al0.2Ga0.8As

When preparing a laser (LD), 30, 40 or more pairs of layers may be required to achieve a reflectance of not less than 99.9%, several to 10 pairs of layers may be sufficient for an LED that is typically required to show a reflectance of not less than 90%.

For example, the luminescent layer 2812 may be made to show a double hetero type structure (clad layer: p-Al0.4Ga0.6As, active layer: p-Al0.13Ga0.87As, clad layer located at the side of the DBR layer: n-Al0.23Ga0.77As). Then, 20 pairs of Al0.2Ga0.8As: 633 |/Al0.8Ga0.2As: 565 Å may be laid to form the n-type DBR layer 2813. With such an arrangement, the doping rate of Si of the n-type DBR layer is within a range between 0.5×1018/cm3 and 5×1018/cm3, preferably within a range between 1×1018/cm3 and 2×1018/cm3 for instance. The doping rate of Si of the n-type clad layer is preferably about 2e18/cm3 relative to n-AlxGa1-xAs (x=0.23) 0.5 n(·?)m.

The electric resistivity of the n-type DBR layer is within a range between about 0.2×10−3·cm and 8×10−3·cm, preferably about 1×10−3·cm.

It is preferable not to remarkably damage the crystallinity of the DBR layer by excessively adding an impurity.

When the luminescent layer is formed by a double hetero type structure, the n-type clad layer and the n-type DBR layer that are arranged close to each other (although a contact layer may be interposed between them) preferably show a relationship as described below. The resistivity of the n-type DBR layer is not less than 10%, preferably not less than 20%, more preferably not less than 35% and substantially equal to lower than the n-type clad layer. If the problem of resistance is not significant for the drive current, the resistivity of the clad layer and that of the n-DBR layer may be made substantially equal to each other.

In the case of the p-type DBR, the efficiency of luminescence can be affected due to absorption of free carrier if the doping rate of carbon or the like is too high. Therefore, it is preferable to use an n-type DBR layer.

The insulating layers 2877, 2887 and 2897 are typically made of silicon oxide.

Gold, platinum, Al, Cu, silver or an alloy of any of them may appropriately be used for the first electrode 2898 and the second electrode 2888.

The second electrode 2898 is preferably held in direct contact with the semiconductor multilayer of the DBR layer 2813.

The substrate 2810 may be made to include a silicon substrate and the DBR layer 2813 may be arranged on the silicon substrate by wan of an insulating region 2811. The insulating region may be formed by using silicon oxide or an organic insulating film.

It is possible to make the member 3850 formed to include the substrate 2810 and the insulating region 2811 have a drive circuit for driving the luminescent device 2812 in the inside.

In this embodiment, 2897 denotes an insulating film. The drive circuit may be arranged in the inside of the member 3850 or in some other part that is not in the inside of the member 3850.

Luminescent devices described above by way of this embodiment may be arranged in array to form an LED printer head and such a printer head can be used to provide an LED printer. An LED printer or a color LED printer can be formed by arranging a plurality of such printer heads.

### Sixth Embodiment: LED Printer

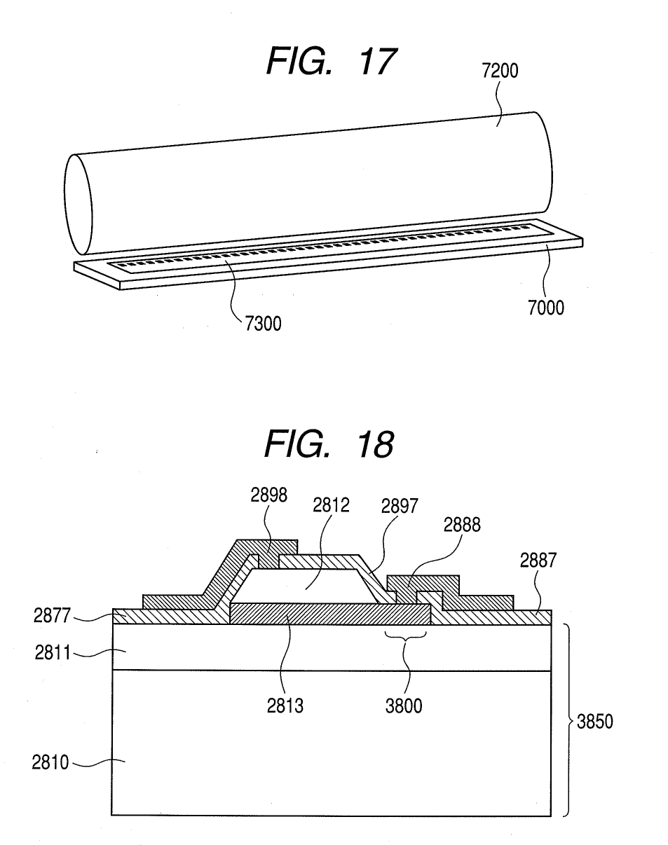

The LED printer of this embodiment is characterized by the following. The LED printer includes an LED array (7300 in FIG. 17), which includes a compound semiconductor formed on a silicon substrate as luminescent layer and a DBR layer formed between the silicon substrate and the luminescent layer. The LED printer additionally includes a photosensitive drum (7200 in FIG. 17) for writing an electrostatic latent image, using the LED array as light source, and a charger (not illustrated) and is characterized in that the LED printer is not provided with a rod lens array between the photosensitive drum and the LED array. While a rod lens array is conventionally arranged between the photosensitive drum and the LED array of an LED printer, it is possible to omit the rod lens array by utilizing a DBR layer according to the present invention. Since the directivity of light emitted from the LED device is improved by using a DBR layer, it is possible to omit the rod lens array whenever necessary.

The LED array itself may be an LED array prepared by the manufacturing method described above in terms of the first through third embodiments of the present invention or by some other method.

Thus, an LED printer prepared by using any of the above-described first through third embodiments may or may not include a rod lens array without departing from the scope of the present invention.

### Seventh Embodiment: LED Array, LED Printer

An LED array of this embodiment has three characteristics as described below.

Firstly, the LED array includes a DBR layer and a luminescent layer arranged in the mentioned order on a silicon substrate having a drive circuit with an insulating layer by way of an insulating layer. Secondly, no organic insulating film is interposed between the luminescent layer and the DBR layer that operates as reflector. Thirdly, the drive circuit and the luminescent layer are electrically connected to each other directly or indirectly by way of the DBR layer.

It is possible to form an LED printer by arranging an LED array having the above listed three characteristics, a photosensitive drum for writing an electrostatic latent image, using the LED array as light source, and a charger. An LED array and an LED printer head according to the present invention are applicable to a color LED printer. Now, a possible configuration of a color printer according to the present invention will be briefly described below. The LED printer includes photosensitive drums that correspond respectively to magenta (M), cyan (C), yellow (Y) and black (K). Thus, the LED printer includes LED printer heads that correspond respectively to the photosensitive drums. The LED printer further includes a conveyor belt for conveying transfer sheets and bringing them into contact with the photosensitive drums, a registration roller for feeding sheets and a fixation roller. If necessary, a charger for eliminating electric charges and/or a sensor for detecting the leading edge of each transfer sheet may be provided.

### Examples

### Example 1

Now, the first example will be described by referring to FIGS. 1A through 5.

A separating layer 1101, which is a p-AlAs layer, a luminescent layer 1102 and an n-DBR layer 1103 are made to grow on a 4-inch GaAs substrate 100 by MOCVD. The separating layer 1101 and the luminescent layer 1102 are made to grow respectively to 100 nm and about 2,000 nm. The particulars of the luminescent layer 1102 include the following.

The luminescent layer 1102 includes a clad layer of p-Al0.4Ga0.6As: 35 nm, an active layer of p-Al0.13Ga0.87As: 300 nm and another clad layer located at the side of the DBR layer of n-Al0.23Ga0.77As: 1,300 nm.

The n-DBR layer 1103 is formed by laying 20 pairs of Al0.2Ga0.8As:633 Å/Al0.8Ga0.2As:565 Å. Thereafter, islands-like regions of 350·m×8 mm are formed on the uppermost DBR layer 1103 by photolithography with 100·m gaps separating them along the four sides thereof as illustrated in FIG. 3.

Subsequently, the 100 *m patterning regions are etched until the separating layer 1101 becomes exposed to produce grooves 1104. The etching process is conducted by using a NH4OH:H2O2=1:50 solution which is held to 30° C. The DBR layer 1103 and the luminescent layer 1102 are etched off and the separating layer 1101 becomes exposed in about 4 minutes.

Then, as illustrated in FIG. 2, a silicon substrate 110 where a drive circuit 1800 is formed is brought in and polyimide that is dissolved in a solvent is applied to the surface thereof by spin coating. Then, a 2·m-thick polyimide film 1111 is produced as the solvent is evaporated. Thereafter, the polyimide film is bonded to the surface of the DBR layer 1103 on the GaAs substrate 100 and subjected to a heat treatment at 280° C. for 2 hours.

The substrate to which the polyimide film is bonded is then immersed in a 5% hydrofluoric acid solution and an ultrasonic wave is applied to it. Consequently, the hydrofluoric acid solution penetrates into the grooves 1104 of the bonding interface to dissolve the separating layer 1101. Then, as a result, the DBR layer 1103 and the luminescent layer 1102 are transferred onto the silicon substrate 110 having a drive circuit by way of the polyimide layer (111).

A luminescent device in the form of an array of luminescent regions of a size of 20×20·m as illustrated in FIG. 5 is produced in the luminescent layer 1102 transferred onto the silicon substrate 110 by way of an ordinary LED forming process. The luminescent regions are separated from each other by gaps of 42·m.

Preferably, a p-type contact layer and an n-type contact layer are arranged in advance respectively on the surface of the luminescent layer 1102 located at the surface side of the substrate and on the lower side of the substrate. The DBR layer 1103 may be made to operate as the n-type contact layer. The n-type contact of the LED is connected to the electrode pad 1900 of the drive circuit by way of the via hole of the polyimide layer 1111.

Then, as a result, an array of about 190 LEDs are formed on a chip having a width of 350·m and a length of 8 mm and connected to the drive circuit. The drive circuit 1800 and the luminescent layer are electrically connected to each other by way of the DBR layer. Alternatively, a contact layer may be formed on the DBR layer and they may be electrically connected to each other by way the contact layer. Then, the contact layer is located between the DBR layer and the insulating film 1111 in FIG. 5. The conduction type regions of the luminescent layer in FIG. 5 located at the side of the DBR layer may be connected to the drive circuit.

Preferably, an AlAs layer or Al oxide should not be used for the low refractive index side layer of the DBR layer so that the DBR layer may hardly be damaged when the separating layer is removed as in this example. No particular limitations are imposed on the materials of the DBR layer when the damage, if any, to the DBR layer is sufficiently small.

A DBR layer and a luminescent device are simply formed in the mentioned order on a GaAs luminescent device substrate of an LED prepared by using a conventional DBR process and the luminescent device substrate is installed in the product. However, as the density of the device (LEDs) rises, the number of bonding wires connecting the driver circuit for driving the LEDs and the LEDs increases to by turn raise the manufacturing cost. Additionally, while a compound semiconductor substrate is used as the luminescent device substrate of ordinary LEDs, a compound semiconductor substrate shows a poor heat diffusing characteristic and energy that does not contribute to luminescence is accumulated as heat as an electric current is made to flow to the device to consequently degrade the luminescent characteristic.

With this example, it is possible to electrically connect the drive circuit and the luminescent device by photolithography without using wires. This means that this example is potentially advantageous from the cost point of view. When the DBR layer and the luminescent layer are transferred onto a silicon substrate, it is possible to secure luminescence with a stable level of luminance without degradation of the luminescent characteristic because the substrate shows a good heat diffusing characteristic.

When a metal reflection film and a luminescent device are not arranged structurally continuously as in the case of the technique of “Imaging Conference Japan 2006, Papers” pp. 11-14 (Fujiwara et al.), it means that a bonding interface exists. Then, the reflection efficiency is degraded further by the micro or macro voids produced along the bonding surface. However, with this example, the DBR that is a reflection film and the luminescent layer are arranged structurally continuously and hence it is possible to avoid the influence of voids.

Thus, with this example, it is possible to overcome the problems of the conventional DBR process and the conventional metal reflection film including increased wire bonding cost that arises when installing a bulk substrate in the DBR process and improve the heat diffusing characteristic of the bulk substrate. Additionally, it is possible to provide a process that can avoid the degradation of the reflection efficiency due to the voids and the adhesive that are found on the conventional metal reflection film and suppress any increase of the overall manufacturing cost. Still additionally, scattered light is reduced rather than diffusion of reflected light from the metal mirror because of the improved directivity. Then, it is possible to reduce the device size and obtain a smaller spot size.

Furthermore, it is possible to realize a print head that is free from any lens system and reduce the distance between the luminescent device array and the photosensitive drums of the printer.

A micro-cavity LED where DBR is arranged on the interface at the side of the silicon substrate and also at the surface side is also within the scope of the present invention. With this arrangement, it is possible to transfer the DBR to the silicon substrate and produce a spot showing an improved directivity. Then, as a result, it is possible to provide a contact type printer head, eliminating any rod lens that requires positional adjustments on the surface of a photosensitive member and has a large number of parts. It is possible to omit a rod lens array not only when DBR is arranged at the opposite sides of the luminescent layer but also when it is arranged only one of the opposite sides of the luminescent layer.

### Example 2

Now, the second example will be described by referring to FIG. 6.

A separating layer 3101, which is a p-AlAs layer, a luminescent layer 3102 and an n-DBR layer 3103 are formed on a 4-inch GaAs substrate 200 to respective thicknesses of 100 nm, about 2,000 nm and about 2,400 nm. Successively, two sets of above-described three layers are made to grow (separating layers 4101, 5101), (luminescent layers 4102, 5102) (DBR layers 4103, 5103). The detailed structure of each layer is same as the corresponding one in Example 1. While three sets of layers including a separating layer, a luminescent layer and a DBR layer are laid one on the other in this example, the number of sets is by no means limited for the purpose of the present invention. Four or more than four sets of layers may be laid.

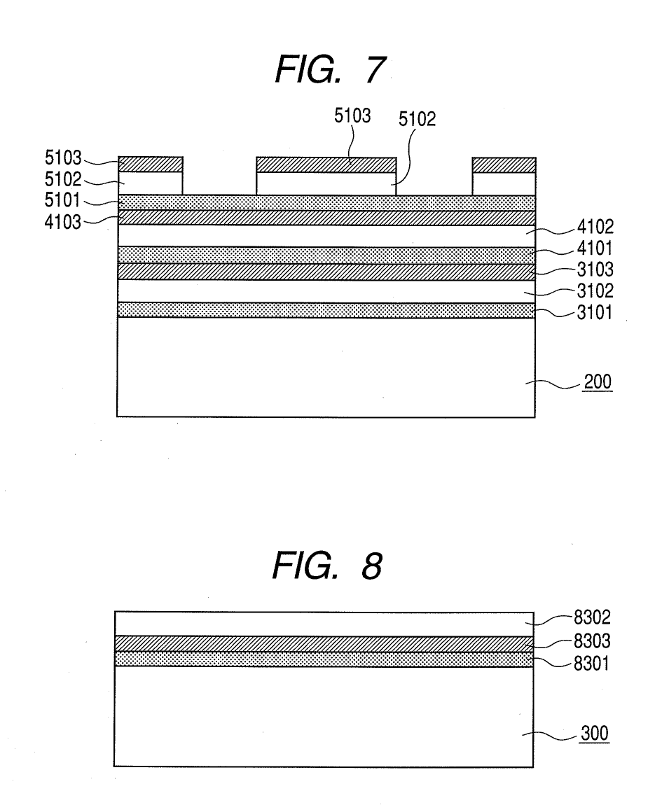

Referring to FIG. 7, the prepared multilayer structure is then etched in a patterning process to a thickness that corresponds to the thickness of the DBR layer 5103 and the luminescent layer 5102 to expose the separating layer 5101 as in Example 1. At this time, the layers (DBR layers, luminescent layers, separating layers) arranged below the separating layer 5101 are not subjected to the patterning process.

Subsequently, the multilayer structure is bonded to a second substrate where a drive circuit is formed by way of an adhesive layer as in Example 1 and then the separating layers are etched off to transfer the DBR layers and the luminescent layers onto the drive circuit. The transferred luminescent layers are subjected to an ordinary LED process to produce an LED array. It is also possible to produce such a structure without using an adhesive layer, or by so-called direct bonding. When no adhesive layer is used, the bonding strength needs to be enhanced by means of a heat treatment. However, the heat treatment has to be conducted at temperature as low as possible to make the existing drive circuit operate properly. In other words, the bonding interface needs to be very clean and flat. It is effective to activate the bonding interface typically by means of plasma in order to accelerate the low temperature bonding.

After the separation, the GaAs substrate (200) carries the DBR layer 4103 at the uppermost surface thereof. Thus, the above transfer process is repeated two times to obtain a total of three transfer substrates.

### Example 3

Now, the third example will be described by referring to FIG. 8.

A separating layer 8301, which is a p-AlAs layer, an n-DBR layer 8303 and a luminescent layer 8302 are formed on a 4-inch GaAs substrate 300 to respective thicknesses of 100 nm, about 2,400 nm and about 2,000 nm. The detailed structure of each layer is same as the corresponding one in Example 1.

Referring to FIG. 9, the prepared multilayer structure is then etched in a patterning process to a thickness that corresponds to the thickness of the luminescent layer 8302 and the DBR layer 8303 to expose the separating layer 8301 as in Example 1.

On the other hand, a temporary substrate 320 having a temporary adhesive agent 8321 on the surface thereof is prepared and the luminescent layer 8302 and the temporary adhesive layer 8321 are bonded to each other.

At this time, an adhesive agent that dissolves into an acrylic type organic solvent is used for the temporary adhesive agent (8321) (for example, TZNR-A Series (product name), available from Tokyo Ohka Kogyo Co., Ltd.). While there are no particular limitations to the temporary substrate 320, a substrate that is resistant against organic solvents used when the adhesive is dissolved such as a quartz substrate may suitably be used, although a silicon substrate or an ordinary glass substrate may alternatively be used.

Then, a 5% hydrofluoric acid solution is injected into the grooves 8304 formed along the bonding interface of the bonded substrate as illustrated in FIG. 9 to etch off the separating layer 8301. As a result, the luminescent layer 8302 and the DBR layer 8303 are transferred onto the temporary substrate 320.

On the other hand, a silicon substrate 310 having a drive circuit formed thereon is prepared and an adhesive layer 8311, which is an organic insulating film, is formed on the surface thereof by spin-coating a polyimide. Subsequently, the DBR layer 8303 that is transferred onto the temporary substrate 320 and becomes exposed and the organic insulating film 8311 are bonded to each other. After evaporating the solvent of the organic insulating film, the bonded layers are further subjected to a heat treatment at 280° C. for 2 hours to increase the bonding strength.

Thereafter, acetone is injected into the grooves 8304 formed along the bonding interface to dissolve the temporary adhesive agent 8321 applied to the temporary substrate 320. Acetone is injected by immersing the bonded substrate into acetone and applying an ultrasonic wave.

Then, as a result, the temporary substrate 320 is separated and the DBR layer 8303 and the luminescent layer 8302 are transferred onto the silicon substrate 310 where a drive circuit is formed.

Referring now to FIG. 12, a LED process is executed as in Example 1 to produce an LED array, which is then connected to the drive circuit.

### Example 4

Three sets of a separating layer, a DBR layer and a luminescent layer are made to grow on a GaAs substrate similar to the one used in Example 3. The temporary substrate transfer step and the silicon drive circuit substrate transfer step same as those of Example 3 are repeated three times as in Example 2 to obtain three LED array substrates.

### Example 5

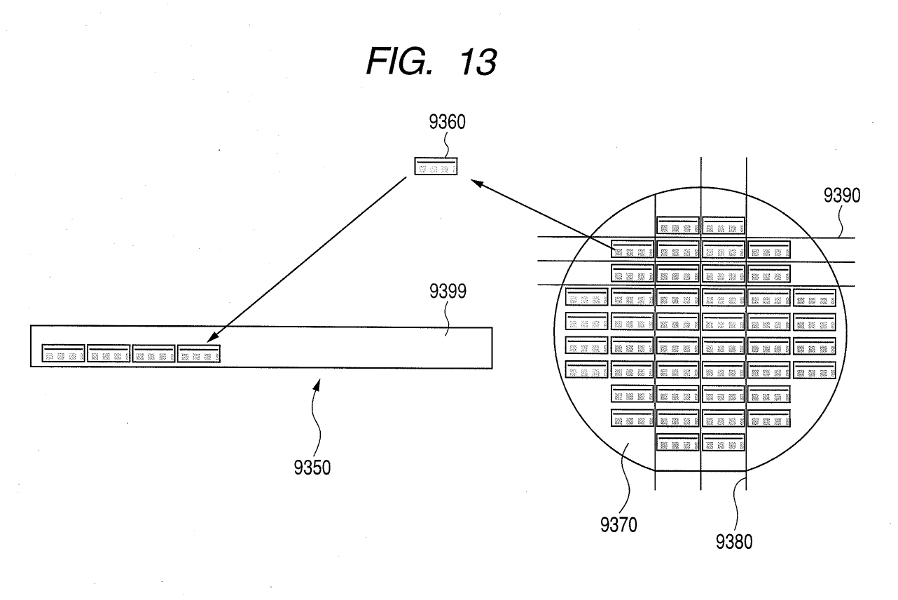

The LED arrays prepared in Examples 1 through 4 have a chip size of 350·m×8 mm and formed on a 4-inch substrate with 100·m gaps separating them along the four sides thereof as illustrated in FIG. 13. In FIG. 13, 9360 denotes an LED chip and 9350 and 9370 respectively denote a printed substrate and a substrate, while 9380 and 9390 denote scribe lines.

The 4-inch substrate is then diced along the 100·m gaps to produce chips and 26 chips are arranged in series on the printed substrate 9350 to form an A4-size LED array as illustrated in FIG. 13.

Then, a part of an LED printer is formed by arranging an A4-size LED array 300, a rod lens array 7100 and a photosensitive drum 7200. The rod lens array is also referred to as Selfoc Lens Array (SLA) or erect image, unity magnification rod lens array. Such a lens array is popularly provided as a strip-shaped lens array that includes an optical system formed by arranging a large number of refractive index distributed lenses (Selfoc) to produce a continuous single image. An SLA (Selfoc Lens array: trademark) is formed by arranging a large number of refractive index distributed lenses (Selfoc).

### Example 6

An epitaxial growth process similar to that of Example 1 is conducted on a GaAs substrate, which is then bonded to a silicon substrate where a drive circuit is formed. The separating layer is etched off as in the etching process of Example 1. An LED forming process similar to that of Example 1 is also conducted except the part connected to the drive circuit.

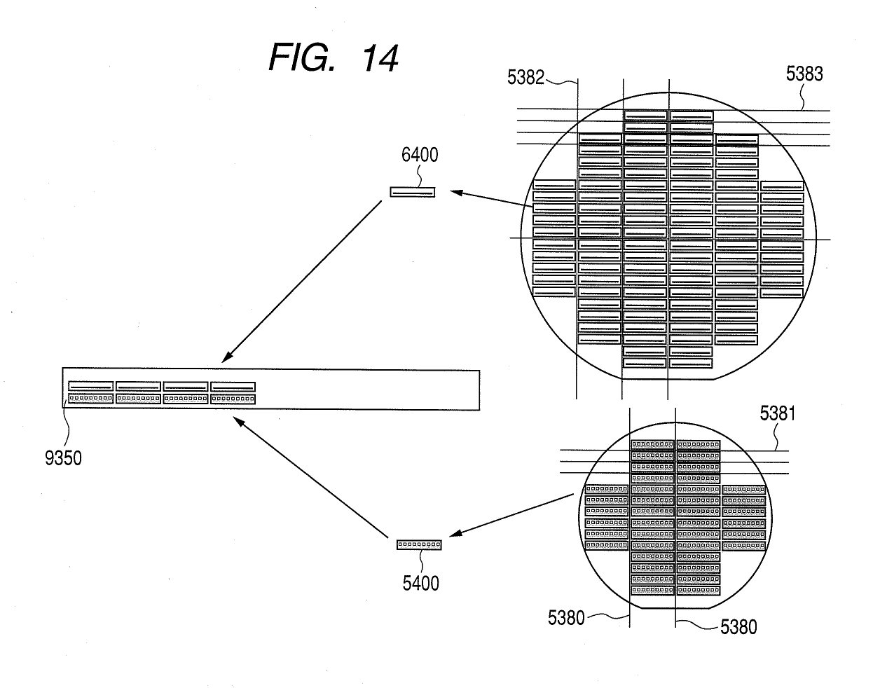

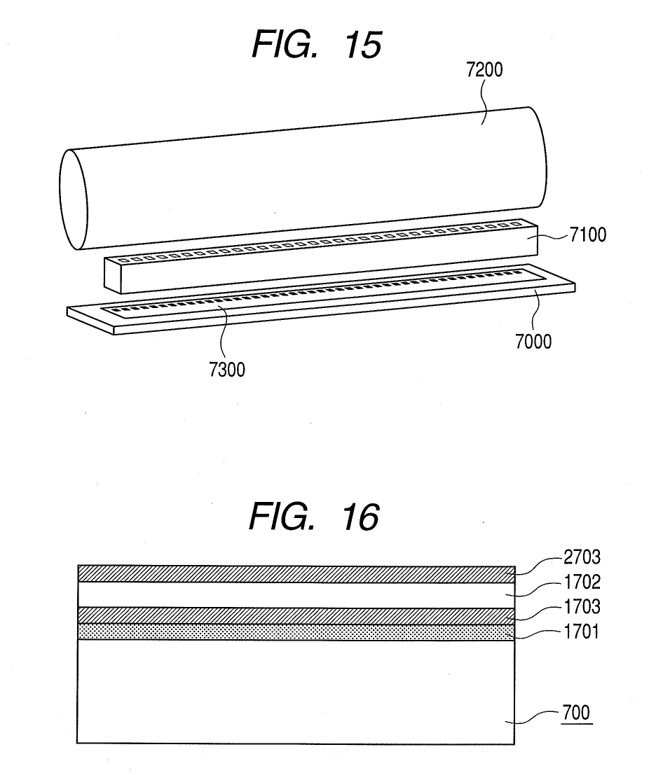

Then, the bonded substrates are diced along the 100*m wide gaps to produce chips (LED chips 5400) and then 26 chips are arranged in series on the printed substrate 9350 to form an A4-size LED array as illustrated in FIG. 14.

A drive circuit prepared separately by way of an ordinary IC process is diced to chips (6400) of the same size and arranged in parallel with the LED array on the printed substrate as illustrated in FIG. 14. The LED chip and the drive circuit chip are connected to each other by wire bonding (not illustrated). In FIG. 14, 5380, 5381, 5382 and 5383 indicate the dicing directions.

### Example 7

A separating layer 1701, a DBR layer 1703, a luminescent layer 1702 and a DBR layer 2703 are sequentially formed on a GaAs substrate 700 by epitaxial growth as illustrated in FIG. 16.

Then, a process similar to that of Example 1 is conducted to produce grooves for etching/separation until the separating layer 1701 becomes exposed.

The obtained LED is turned into an array, which is then used in a printer head (LED array 7300, printed substrate 7000) as in Example 5. The light radiation angle of the LED of this example can be reduced than before. Therefore, the use of a rod lens array for converging radiated light is not necessary when producing an LED printer.

When the use of a rod lens array is eliminated in the arrangement of FIG. 17, a protrusion structure may be provided on the printed substrate to adjust or maintain the gap before the photosensitive drum 7200 and the LED array. Such a protrusion may be arranged at each of the opposite longitudinal ends of the array of the printed substrate. If the problem of abrasion between the photosensitive drum and the LED array is negligible, they may brought into tight contact with each other.

While the present invention has been described with reference to exemplary embodiments, it is to be understood that the invention is not limited to the disclosed exemplary embodiments. The scope of the following claims is to be accorded the broadest interpretation so as to emcompass all such modifications and equivalent structures and functions.

This application claims the benefit of Japanese Patent Application No. 2006-293306, filed on Oct. 27, 2006, Japanese Patent Application No. 2006-310384, filed on Nov. 16, 2006 and Japanese Patent Application No. 2007-060362, filed on Mar. 9, 2007, which are hereby incorporated by reference herein in their entirety.

1. An LED array manufacturing method comprising:
a step of forming a luminescent layer and a DBR layer on a first substrate with a separating layer interposed between the luminescent or DBR layer and the first substrate;
a patterning step of patterning the DBR layer and the luminescent layer to make them show an islands-like profile;
a bonding step of bonding the luminescent or DBR layer and a second substrate with an insulating layer interposed between the luminescent or DBR layer and the second substrate; and
a separating step of separating the first substrate and the luminescent or DBR layer from each other by etching and removing the separating layer.

2. The method according to claim 1, wherein the separating layer is made of AlAs or AlxGa1-xAs (0.7≦x≦1.0).

3. The method according to claim 1, wherein the low refractive index layers of the DBR layer whose refractive index is lower than the remaining layers is made of a material selected from AlxGa1-xAs (0≦x≦0.8), AlInGaP type materials and AlGaP type materials.

4. The method according to claim 1, wherein the second substrate is a silicon substrate.

5. The method according to claim 1, wherein the luminescent layer and the DBR layer are formed in the mentioned order from the separating layer side or the DBR layer and the luminescent layer are formed in the mentioned order from the separating layer side on the first substrate with the separating layer interposed between them.

6. The method according to claim 1, wherein the separating step is conducted after the bonding step.

7. The method according to claim 1, wherein the separating step is conducted after bonding the luminescent layer and a temporary bonding substrate after the patterning step and subsequently the bonding step is conducted.

8. The method according to claim 1, wherein the patterning step is a step of patterning the luminescent layer to make it show an islands-like profile by device isolation such that each island includes a plurality of luminescent sections, the luminescent sections being subsequently made to correspond to individual luminescent spots by device isolation after the separating step.

9. The method according to claim 1, wherein the patterning step is a step of patterning the luminescent layer to make it show an islands-like profile by device isolation such that each island corresponds to each luminescent spot.

10. The method according to claim 1, wherein the patterning step of patterning the DBR layer and the luminescent layer to make them show an islands-like profile is a step of forming regions each including a plurality of luminescent devices arranged in array and having a size which agrees with a chip size adopted in dicing the second substrate.

11. The method according to claim 1, wherein the patterning step of patterning the DBR layer and the luminescent layer to make them show an islands-like profile is a step of forming regions each including a plurality of luminescent devices arranged in array and having a size smaller than a chip size adopted in dicing the second substrate while the regions are arranged at a pitch equal to the chip size.

12. The method according to claim 1, wherein a semiconductor circuit is formed on the second substrate to drive a plurality of luminescent sections formed by dividing the luminescent layer and the DBR layer to make them show an islands-like profile; and
the method further comprises a connecting step of electrically connecting the luminescent sections and electrode parts of the semiconductor circuit after the bonding step and the separating step.

13. The method according to claim 12, wherein the connecting step is a step of electrically connecting the DBR layer divided to show an islands-like profile so as to form luminescent sections and the electrode parts.

14. The method according to claim 1, wherein the luminescent layer is sandwiched between the DBR layer and another DBR layer different from the DBR layer.

15. The method according to claim 1, wherein a plurality of sets, each having the separating layer, the luminescent layer and the DBR layer, are laid one on the other on the first substrate.

16. The method according to claim 1, wherein the insulating layer is an organic insulating film.

17. An LED array manufacturing method comprising:
a step of sequentially forming a separating layer, a luminescent layer and a DBR layer on a surface of a first semiconductor substrate and bonding the first semiconductor substrate to a second substrate carrying a semiconductor circuit formed thereon by way of an insulating layer;
a step of transferring the luminescent layer and the DBR layer onto the second substrate by etching off the separating layer;
a step of turning the transferred luminescent layer into an array of a plurality of luminescent sections; and
a step of electrically connecting the plurality of luminescent sections and electrode parts of the semiconductor circuit for controlling on/off of the luminescent sections.

18. An LED printer comprising:
an LED array prepared by an LED array manufacturing method according to claim 1;
a photosensitive drum for writing an electrostatic latent image, using the LED array as light source; and
a charger;
no rod lens array being arranged between the photosensitive drum and the LED array.

19. An LED printer comprising:
an LED array having a luminescent layer of a compound semiconductor formed on a silicon substrate and a DBR layer arranged between the silicon substrate and the luminescent layer;
a photosensitive drum for writing an electrostatic latent image, using the LED array as light source; and
a charger;
no rod lens array being arranged between the photosensitive drum and the LED array.

20. An LED array comprising a DBR layer and a luminescent layer formed in the mentioned order on a silicon substrate having a drive circuit with an insulating layer interposed between the DBR layer and the silicon substrate;
no organic insulating film being interposed between the luminescent layer and the DBR layer operating as reflector;
the drive circuit and the luminescent layer being electrically connected to each other directly or indirectly by way of the DBR layer.

21. An LED printer comprising:
an LED array according to claim 20;
a photosensitive drum for writing an electrostatic latent image, using the LED array as light source; and
a charger;
no rod lens array being arranged between the photosensitive drum and the LED array.

22. A luminescent device comprising:
a DBR layer having a semiconductor film and a luminescent layer formed in the mentioned order on a substrate;
a first electrode for flowing a drive current to the luminescent layer being electrically connected to the luminescent layer at the side opposite to the DBR layer;
a second electrode for flowing a drive current to the luminescent layer being electrically connected to the semiconductor film of the DBR layer at the side of the luminescent layer.

23. The device according to claim 22, wherein a region free from the luminescent layer is arranged on the DBR layer and the DBR layer in the region and the second electrode are electrically connected to each other.

24. The device according to claim 22, wherein the DBR layer is an n-type DBR layer.

25. The device according to claim 22, wherein the second electrode is directly connected to the semiconductor multilayer film of the DBR layer.

26. The device according to claim 22, wherein the substrate is formed to include a silicon substrate and the DBR layer is formed on the silicon substrate with an insulating region interposed between them.

27. The device according to claim 26, wherein the member formed to include the silicon substrate and the insulating region has in the inside thereof a drive circuit for driving the luminescent device.

28. An LED printer head comprising the luminescent device according to claim 22 arranged in array.

29. An LED printer comprising a plurality of printer heads, each having luminescent devices according to claim 22 arranged in array.

30. A color LED printer comprising a plurality of printer heads, each having the luminescent device according to claim 22 arranged in array.
